(19) United States
(12) Patent Application Publication
(10) Pub. No.: US 2025/0374531 A1
(43) Pub. Date: Dec. 4, 2025

(54) MEMORY CONNECTION WITH OXIDE-NITRIDE-SILICON (ONP) SCHEME

(71) Applicant: Applied Materials, Inc., Santa Clara, CA (US)

(72) Inventors: Wonjoo Kim, San Jose, CA (US); Mahendra Pakala, Saratoga, CA (US); Michel Frei, Palo Alto, CA (US); Jong Mun Kim, San Jose, CA (US)

(73) Assignee: Applied Materials, Inc., Santa Clara, CA (US)

(21) Appl. No.: 18/782,320

(22) Filed: Jul. 24, 2024

Related U.S. Application Data
(60) Provisional application No. 63/655,160, filed on Jun. 3, 2024.

(51) Int. Cl. H10B 12/00

(52) U.S. Cl. CPC H10B 12/488; H10B 12/02

(57) ABSTRACT

Methods of manufacturing a semiconductor device are provided. A memory stack comprising alternating layers of a plurality of silicon (Si) layers and a plurality of silicon germanium (SiGe) layers is formed on a substrate. The memory stack includes a word line contact region and a memory array region. An oxide-nitride-silicon (ONP) stack is formed and a metal replacement is used simultaneously for both the memory array region and for the word line contact region.

### CROSS-REFERENCE TO RELATED APPLICATIONS

This application claims priority to U.S. Provisional Application No. 63/655,160, filed Jun. 3, 2024, the entire disclosure of which is hereby incorporated by reference herein.

### TECHNICAL FIELD

Embodiments of the disclosure generally relate to memory devices and methods for forming memory devices. In particular, embodiments of the disclosure pertain to methods of forming word line connections between the memory array and word line contact area of memory devices.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time.

DRAM memory circuits are manufactured by replicating billions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

Current methods of manufacturing memory devices are based on oxide-silicon stacks, e.g., OP stacks. Such methods may be problematic when forming the word line connection between the memory array and the word line contact. Due to the nature of the current word line formation scheme in 3D DRAM, the metal replacement for word line needs to be made separately between the memory array word line and the staircase word line. The separate and duplicate metal replacement scheme will create longer process times and higher process costs. Additionally, it is challenging to have a strong connection between the memory array word line and the staircase word line since the process margin for the connection is narrow.

Accordingly, there is a need for improved methods of manufacturing semiconductor memory devices.

### SUMMARY

One or more embodiments of the disclosure are directed to methods of manufacturing a semiconductor device. In one or more embodiments, the method comprises: forming a memory stack comprising alternating layers of a plurality of silicon (Si) layers and a plurality of silicon germanium (SiGe) layers on a substrate, the memory stack including a word line contact region and a memory array region; forming a plurality of memory units through the memory array region of the memory stack; selectively etching the plurality of silicon germanium (SiGe) layers in both the word line contact region and the memory array region through the plurality of memory units to form a first opening; trimming the plurality of silicon (Si) layers to form a plurality of trimmed silicon (Si) layers; depositing a nitride material on the plurality of trimmed silicon (Si) layers to form a plurality of nitride layers in both the word line contact region and the memory array region; and depositing and oxide material on the plurality of nitride layers to form a plurality of oxide layers in both the word line contact region and the memory array region.

Additional embodiments of the disclosure are directed to methods of manufacturing a semiconductor device. In one or more embodiments, the method comprises: selectively etching a plurality of silicon germanium (SiGe) layers in both a word line contact region and a memory array region of a memory stack on a substrate to form a plurality of first openings adjacent a plurality of silicon (Si) layers; depositing a nitride material on the plurality of silicon (Si) layers to form a plurality of nitride layers in both the word line contact region and the memory array region; and depositing an oxide material on the plurality of nitride layers to form a plurality of oxide layers in both the word line contact region and the memory array region.

### BRIEF DESCRIPTION OF THE DRAWINGS

So that the manner in which the features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 depicts a process flow diagram of a method for forming a semiconductor device in accordance with some embodiments of the present disclosure;

FIG. 2A illustrates a cross-sectional view of a memory device according to one or more embodiments of the disclosure;

FIG. 2B illustrates a cross-sectional view of a memory device according to one or more embodiments of the disclosure;

FIG. 2C illustrates a cross-sectional view of a memory device according to one or more embodiments of the disclosure;

FIG. 2D illustrates a cross-sectional view of a memory device according to one or more embodiments of the disclosure;

FIG. 2E illustrates a cross-sectional view of a memory device according to one or more embodiments of the disclosure;

FIG. 2F illustrates a cross-sectional view of a memory device according to one or more embodiments of the disclosure;

FIG. 3A illustrates a top-down view of a memory device according to one or more embodiments of the disclosure;

FIG. 3B illustrates a cross-sectional view of a memory device according to one or more embodiments of the disclosure;

FIG. 3C illustrates a cross-sectional view of a memory device according to one or more embodiments of the disclosure; and

FIG. 4 illustrates a cluster tool according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas”, and the like are used interchangeably to refer to any gaseous species that can react with the substrate surface.

The term “on” indicates that there is contact between elements, and there may be intervening elements or layers. The term “directly on” indicates that there is direct contact between elements with no intervening elements.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

The manufacturing of a DRAM cell includes the fabrication of a transistor, a capacitor, and three contacts: one each to the bit line, the word line, and the reference voltage. There is a continuous desire to decrease the size of individual cells and to increase memory cell density to allow more memory to be included on a single memory chip, especially for densities greater than 256 Megabits. Limitations on cell size reduction include the passage of both active and passive word lines through the cell, the size of the cell capacitor, and the compatibility of array devices with non-array devices.

As used herein, the term “bit line” refers to a layer of material that is an electrical conductor. In one or more embodiments, the channel comprises one or more silicon, polysilicon, epitaxial silicon, amorphous silicon, doped silicon, strained silicon, silicon on insulator (SOI), carbon doped silicon oxides, SiGe, germanium, Epi Ge, Epi SiGe, gallium arsenide, GaN, InP, carbon nanotube, and any other materials such as 2D TMD metals, metal oxides, metal nitrides, metal alloys, and other conductive materials, depending on the application. In one or more embodiments, the bit line includes, without limitation, growth silicon. Bit line may be exposed to in-situ or ex-situ pretreatment and post-treatment process to fuse, freeze, heat, microwave, polish, etch, reduce, oxidize, hydroxylate, anneal, UV cure, e-beam cure and/or bake the bulk or surface of the bit line. In addition to film processing directly on the surface or bulk structure of the bit line itself, in the present disclosure, any of the film processing steps disclosed may also be performed on an underlayer formed on the bit line as disclosed in more detail below, and the term “bit line surface” is intended to include such underlayer as the context indicates. Thus, for example, where a film/layer or partial film/layer has been deposited onto a bit line surface, the exposed surface of the newly deposited film/layer becomes the bit line surface.

As used herein, the term “capacitor” refers to an electrical component of a memory cell. A capacitor has two electrical conductors separated by electrically insulating material.

As used herein, the term “active” or “memory layer” refers to a layer of material in which a channel, a bit line, a word line, or a capacitor can be made. In one or more embodiments, the memory layer comprises one or more of silicon or doped silicon. For example, in one or more embodiments, the memory layer is selected from one or more of Si, or IGZO (In—Ga—Zn Oxide).

One or more embodiments of the disclosure are described with reference to the Figures. In the method of one or more embodiments, memory devices, e.g., 3D DRAM, are fabricated. One or more embodiments advantageously provide a robust word line metal connection between the memory array and the word line contact area. The memory device, e.g., 3D DRAM, of one or more embodiments uses an oxide-nitride-silicon stack, also referred to as an ONP stack. In one or more embodiments, a metal replacement is used for both the memory array and for the word line contact area. The method of one or more embodiments advantageously results in a decrease in the amount of time required for manufacturing and provides cost savings during processing.

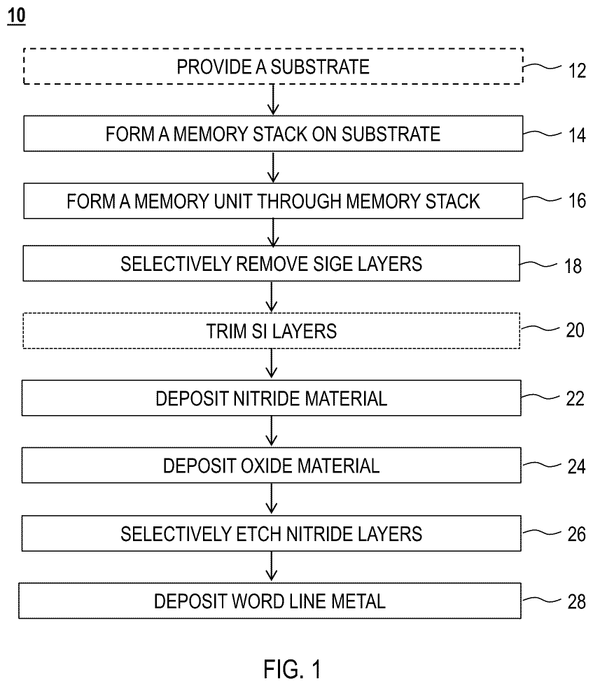

FIG. 1 illustrates a process flow diagram for a method 10 of forming a semiconductor device in accordance with some embodiments of the present disclosure. The method 10 is described below with respect to FIGS. 1, 2A-2F, and 3A-3C.

The method 10 of one or more embodiments may be part of a multi-step fabrication process of a semiconductor device. Accordingly, the method may be performed in any suitable process chamber coupled to a cluster tool. The cluster tool may include process chambers for fabricating a semiconductor device, such as chambers configured for etching, deposition, atomic layer deposition (ALD), physical vapor deposition (PVD), chemical vapor deposition (CVD), oxidation, or any other suitable chamber used for the fabrication of a semiconductor device.

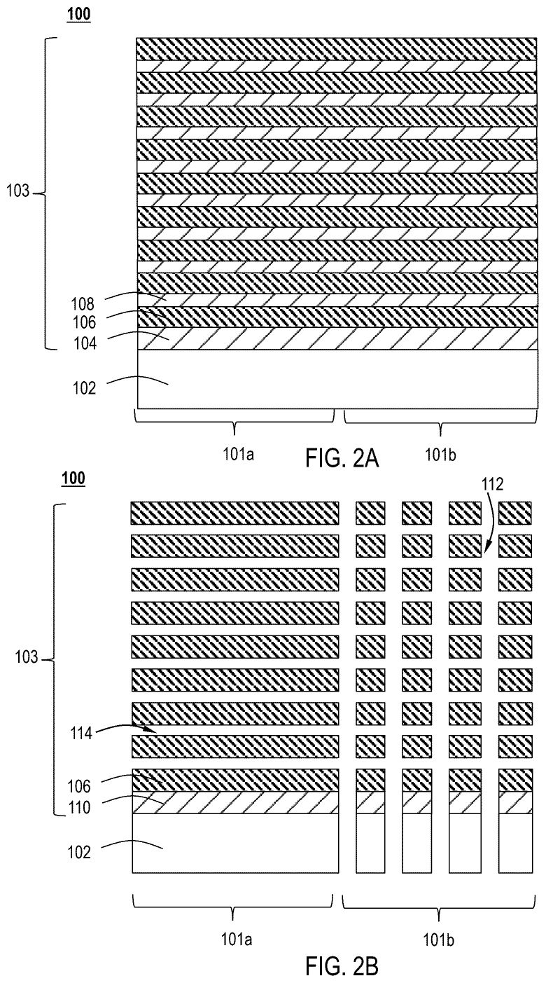

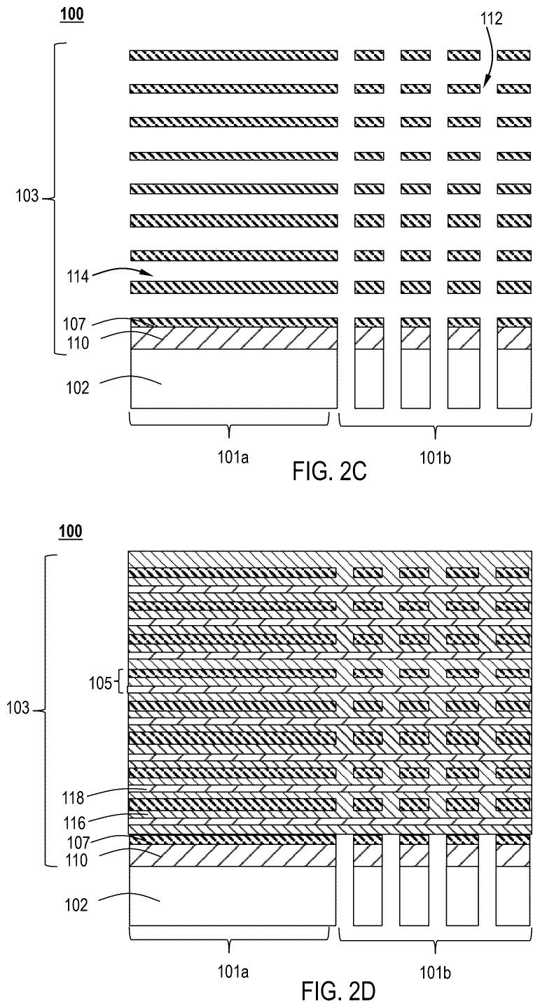

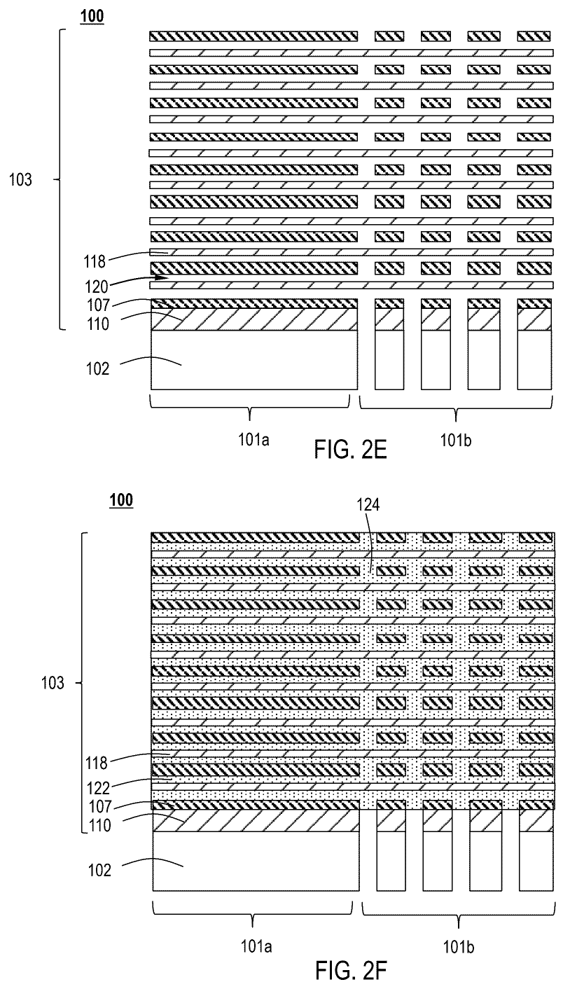

As illustrated in FIGS. 1 and 2A, the method 10 begins at operation 12, by providing a substrate 102. As used in this manner, the term “providing” means that the substrate 102 is made available for processing. For example, the substrate 102 can be provided by being placed within a suitable processing chamber. In some embodiments, the substrate 102 may be a bulk semiconductor substrate. The term bulk semiconductor substrate refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, or other suitable semiconducting materials. In some embodiments, the semiconductor material is silicon (Si). In some embodiments, the semiconductor material may be a doped material, such as n-doped silicon (n-Si), or p-doped silicon (p-Si). In some embodiments, the substrate may be doped using any suitable process such as an ion implantation process. In some embodiments, the substrate may be doped to provide a high dose of dopant at a first location of the surface of the substrate 102 in order to prevent parasitic bottom device turn on. For example, in some embodiments, the surface of the substrate may have a dopant density of about 10¹⁸ atoms/cm³ to about 10¹⁹ atoms/cm³.

In one or more embodiments, as illustrated in FIG. 1 and FIG. 2A, at operation 14, a memory stack 103 is formed on a top surface of the substrate 102. The memory stack 103 includes both a memory array region 101b and word line contact region 101a. The memory array region 101b is within the memory stack 103 and contains the components of the memory (e.g., capacitor and transistors). The particular components of the memory array region 101b are omitted from the drawings for descriptive purposes. The skilled artisan, however, will be familiar with the formation and arrangement of these components to arrive at a view as described, for example, with respect to FIGS. 1 through 2F.

In one or more embodiments, the memory stack 103 comprises alternating layers of a plurality of silicon layers 106 and a plurality of silicon germanium (SiGe) layers 104, 108. The various layers described can be formed by any suitable technique known to the skilled artisan. For example, one or more of the layers can be formed by epitaxy, i.e., epitaxial growth, chemical vapor deposition, atomic layer deposition, physical vapor deposition, ion implantation, etc. In some embodiments, each of the plurality of silicon layers 106 and the plurality of silicon germanium (SiGe) layers 104, 108 are epitaxially grown.

The individual alternating layers may be formed to any suitable thickness. In some embodiments, the thickness of each silicon layer 106 is approximately equal. In one or more embodiments, alternating silicon germanium (SiGe) layers 108 are about five to eight times thinner than the intervening silicon layer 106.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g., aluminum precursor) is pulsed into the reaction zone followed by a first time-delay. Next, a second precursor or compound B (e.g., oxidant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

As used herein, the term “epitaxy” refers to a type of crystal growth or material deposition in which new crystalline layers are formed with one or more well-defined orientations with respect to a crystalline seed layer. The deposited crystalline film is called an epitaxial layer.

Referring to FIG. 1 and FIG. 2B, at operation 16, one or more embodiments of the method 10 comprise forming a plurality of channels or memory units 112 through the memory stack 103 to the substrate 102 surface (or a distance into the substrate) by lithography. In some embodiments, opening the memory unit 112 comprises etching through the memory stack 103 to the substrate 102 (or a distance into the substrate 102). Referring to FIG. 2B, the memory unit 112 has sidewalls that extend through the memory stack 103 exposing surfaces of the plurality of silicon (Si) layers 106 and surfaces of the plurality of silicon germanium (SiGe) layers 108. The memory unit 112 extends to the substrate 102 so that the bottom of the memory unit 112 is a top surface of the substrate 102, or, as illustrated in FIG. 2B, such that the memory unit 112 extends completely through the substrate 102.

In one or more embodiments, the memory unit 112 can have a high aspect ratio. As used herein, the term “high aspect ratio” refers to a feature having a height: width ratio greater than or equal to about 10, 20, 50, 100, or more.

In one or more embodiments, the plurality of channels or memory units 112 is formed in the memory array region 101b of the memory stack 103 and not in the word line contact region 101a of the memory stack 103. The skilled artisan will understand how to form the plurality of channels using lithography.

With reference to FIGS. 1 and 2C, at operation 18, after formation of the plurality of memory units 112 through the memory stack 103, each of the plurality of silicon germanium (SiGe) layers 108 are selectively etched from the memory stack 103 through the plurality of memory units 112 in both the word line contact region 101a and in the memory array region 101b to form a plurality of first openings 114. The skilled artisan will understand how to etch the plurality of silicon germanium (SiGe) layers 108. The plurality of silicon germanium (SiGe) layers 108 may be removed by any suitable means known to the skilled artisan. In one or more embodiments, the plurality of silicon germanium (SiGe) layers 108 are removed by selective etching, e.g., selective wet etching or selective dry etching. Removal of the plurality of silicon germanium (SiGe) layers 108 forms a plurality of first openings 114.

Referring to FIG. 1 and FIG. 2C, in one or more embodiments, at operation 20, the plurality of silicon (Si) layers 106 are then trimmed to decrease the thickness of the plurality of silicon (Si) layers 106 in both the word line contact 101a region and in the memory array region 101b and form a plurality of trimmed silicon (Si) layers 107. The plurality of silicon (Si) layers 106 are trimmed both from a top surface and from a bottom surface. In one or more embodiments, the plurality of silicon (Si) layers 106 have a first thickness in a range of from 40 nm to 100 nm prior to trimming and the plurality of trimmed silicon (Si) layers 107 have a second thickness in a range of from 10 nm to 40 nm after trimming. Any suitable process may be used to trim the plurality of silicon (Si) layers 106. In some embodiments, the plurality of silicon (Si) layers 106 may be trimmed using one of more of etching or planarization and the like.

With reference to FIG. 1 and FIG. 2D, at operation 22, in one or more embodiments, a nitride material 116 is deposited on the plurality of trimmed silicon (Si) layers 107. The nitride material 116 may comprise any suitable nitride material known to the skilled artisan. In one or more embodiments, the nitride material 116 comprises silicon nitride (SiN).

In one or more embodiments, the nitride material 116 is deposited in the plurality of first openings 114 and in the plurality of memory units 112 on the plurality of trimmed silicon (Si) layers 106 to form a plurality of nitride layers in both the word line contact region 101a and the memory array region 101b. In specific embodiments, silicon nitride is deposited in the plurality of first openings 114 and in the plurality of memory units 112 on the plurality of trimmed silicon (Si) layers 106 to form a plurality of silicon nitride (SiN) layers in both the word line contact region 101a and in the memory array region 101b.

Referring to FIG. 1 and FIG. 2D, at operation 24, in one or more embodiments, an electrical insulating material 118 is then deposited in the plurality of first openings 114 and in the plurality of memory units 112 on the plurality of nitride layers 116 to form a plurality of oxide layers. In one or more embodiments, with the addition of the plurality of oxide layers, the memory stack 103 comprises a plurality of alternating layers of oxide layers 118, nitride layers 116, and trimmed silicon (Si) layers 107, forming an oxide-nitride-silicon stack, also referred to as an ONP stack 105.

The electrical insulating material 118 may comprise any suitable electrical insulating material known to the skilled artisan. In one or more embodiments, the electrical insulating material 118 comprises silicon oxide (SiOₓ). Accordingly, in one or more embodiments, silicon oxide (SiOₓ) is then deposited in the plurality of first openings 114 and in the plurality of memory units 112 on each of the plurality of nitride layers 116 to form a plurality of silicon oxide layers in both the word line contact region 101a and in the memory array region 101b.

With reference to FIG. 1 and FIG. 2E, at operation 26, in one or more embodiments, the plurality of nitride layers 116 are selectively etched to form a plurality of second openings 120 in both the word line contact region 101a and in the memory array region 101b. The skilled artisan will understand how to selectively etch the plurality of nitride layers 116 to form the plurality of second openings 120.

Referring to FIG. 1 and FIG. 2F, at operation 28, a word line metal 122 is then deposited in the plurality of second openings 120 simultaneously in both the word line contact region 101a and the memory array region 101b. The word line metal 122 may comprise any suitable metal known to the skilled artisan. In one or more embodiments, the word line metal 122 comprises a bulk metal comprising one or more of copper (Cu), cobalt (Co), tungsten (W), aluminum (Al), ruthenium (Ru), iridium (Ir), molybdenum (Mo), platinum (Pt), tantalum (Ta), titanium (Ti), or rhodium (Rh). In one or more embodiments, the word line metal 122 comprises tungsten (W). In other embodiments, the word line metal 122 comprises ruthenium (Ru). In one or more embodiments, word line metal 122 comprises one or more of a metal, a metal nitride, a conductive metal compound, and a semiconductor material. The metal may be selected from one or more of tungsten (W), molybdenum (Mo), tantalum (Ta), niobium (Nb), osmium (Os), zirconium (Zr), iridium (Ir), rhenium (Re), or titanium (Ti). The metal nitride may be selected from one or more of titanium nitride (TiN), tantalum nitride (TaN), tungsten nitride (WN), molybdenum nitride (MoN), and zirconium nitride (ZrN). The conductive metal compound may be selected from one or more of tungsten oxide (WOx), ruthenium oxide (RuOx), and iridium oxide (IrOx). The semiconductor material may be selected from one or more of silicon (Si), silicon germanium (SiGe), and germanium (Ge).

In one or more embodiments, a robust word line metal connection 124 is provided between the memory array 101b and the word line contact area 101a. The memory device 100, e.g., 3D DRAM, of one or more embodiments uses an oxide-nitride-silicon stack, also referred to as an ONP stack 105. As used herein, the “robust connection” has no or substantially no interrupted connection of word line metal between the memory array region 101b and the word line contact region 101a.

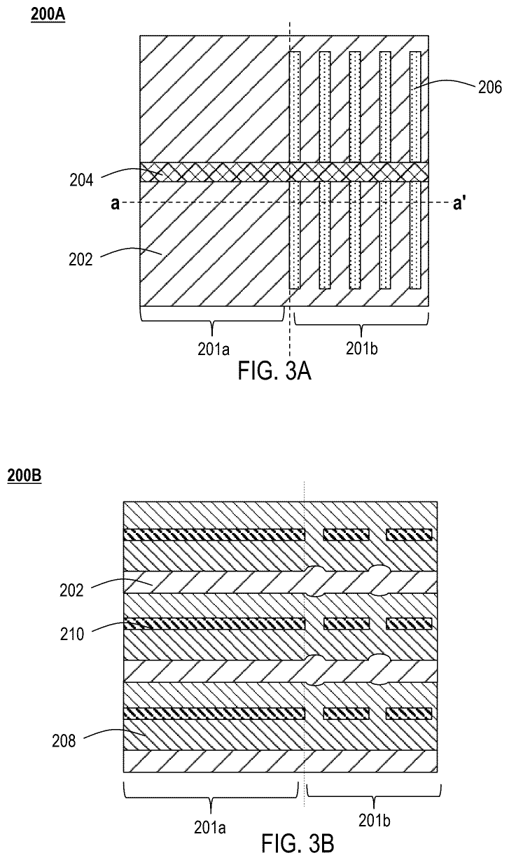

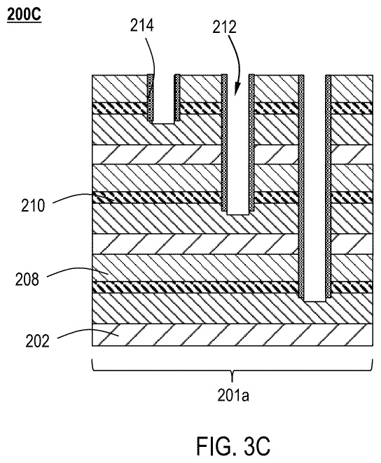

FIGS. 3A-3C illustrate various views of the word line connection using the ONP stack. FIG. 3A is a top-down view of a device 200A showing a vertical isolation pattern 206 only in the memory array region 201b and not in the word line contact region 201a. In one or more embodiments, line trench pattern 204, removing all Si/SiGe stacks from top to bottom used for SiGe removal, Si slimming, SiN/SiO₂ deposition, and WL metal replacement will be present in both the memory array region 201b and in the word line contact region 201b. In subsequent embodiments, the line trench pattern 204 will be fixed with an oxide material.

FIG. 3B illustrates a cross-sectional view taken along line a-a′ in FIG. 3A. As illustrated in FIG. 3B, there is no nitride 208 discontinuity between the word line contact region 201a and the memory array region 201b. As illustrated in FIG. 3B, no word line metal has yet been deposited. In one or more embodiments, an insulating material 202 including, but not limited to, silicon oxide (SiOx), 210 slimmed silicon layer, and 208 nitride layer.

FIG. 3C illustrates a cross-sectional view of the device 200C. The nitride layer 208 will be replaced by a word line metal material during subsequent processing. The word line contact will be covered with APF for uncontrolled silicon removal during gate-all-around polysilicon 210 removal. In one or more embodiments, the word line contact will be covered with sacrificial material such as carbon, amorphous/poly Si and the like to be removed more easily during later processing steps. In one or more embodiments, the polysilicon is removed using tetramethyl ammonium hydroxide (TMAH) or other suitable chemistries.

The method of one or more embodiments is an integrated method. In one or more embodiments, the method may be performed in one or more processing chamber without breaking vacuum.

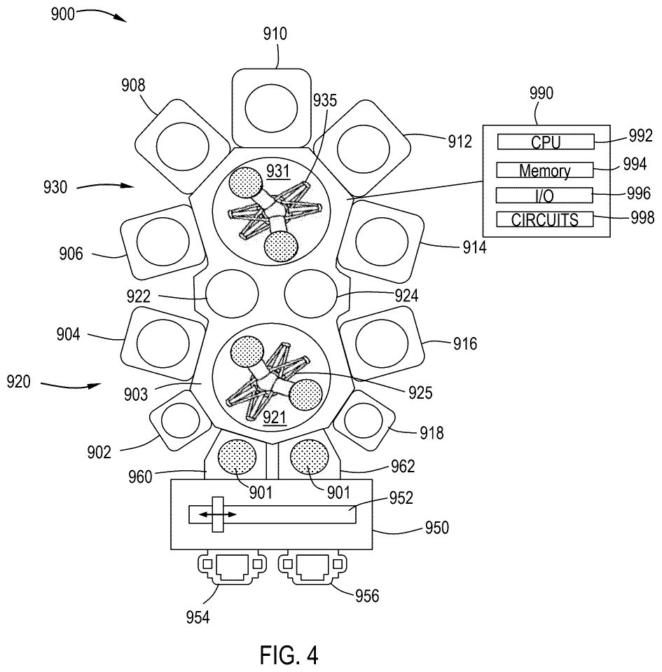

Additional embodiments of the disclosure are directed to processing tools 900 for the formation of the logic or memory devices and methods described, as shown in FIG. 4. The method 10 of one or more embodiments may be an integrated method. In one or more embodiments, the method 10 may be performed in one or more processing chamber without breaking vacuum between any of the operations 12, 14, 16, 18, 20, 22, 24, 26, and 28.

In one or more embodiments, the processing tool 900 is a cluster tool that includes at least one central transfer station, e.g., first transfer chamber 921, and second transfer chamber 931, with a plurality of sides. At least one robot 925, 935 is positioned within the at least one central transfer station, e.g., first transfer chamber 921, and second transfer chamber 931, and is configured to move a robot blade and a wafer to each of the plurality of sides.

In one or more embodiments, the processing tool 900 is a cluster tool that comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a deposition (ALD/CVD/PVD) chamber, and an epitaxial growth chamber. The particular arrangement of process chambers and components can be varied depending on the cluster tool and should not be taken as limiting the scope of the disclosure.

In the embodiment shown in FIG. 4, a factory interface 950 is connected to a front of the processing tool 900. The factory interface 950 includes a loading chamber 954 and an unloading chamber 956 on the front of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the processing tool 900, e.g., a cluster tool. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

In one or more embodiments, the processing tool 900 is a cluster tool that has a first section 920 and a second section 930. The first section 920 is connected to the factory interface 950 through load lock chambers 960, 962. The first section 920 includes a first transfer chamber 921 with at least one robot 925 positioned therein. The at least one robot 925 is also referred to as a robotic wafer transport mechanism. The first transfer chamber 921 is centrally located with respect to the load lock chambers 960, 962, processing chambers 902, 904, 916, 918, and buffer chambers 922, 924. The at least one robot 925 of some embodiments is a multi-arm robot capable of independently moving more than one wafer at a time. In some embodiments, the first transfer chamber 921 comprises more than one robotic wafer transfer mechanism. The at least one robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising one or more of a pre-cleaning chamber, a deposition chamber, and a controller connected to the central transfer station and the plurality of process stations, the controller configured to activate the robot to move the wafer between process stations, and to control a process occurring in each of the process stations. In one or more embodiments, the processing tool is maintained under vacuum during each processing operation.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing a semiconductor device, the method comprising:
forming a memory stack comprising alternating layers of a plurality of silicon (Si) layers and a plurality of silicon germanium (SiGe) layers on a substrate, the memory stack including a word line contact region and a memory array region having a plurality of memory units;
selectively etching the plurality of silicon germanium (SiGe) layers in both the word line contact region and the memory array region to form a first opening;
depositing a nitride material on the plurality of silicon (Si) layers to form a plurality of nitride layers in both the word line contact region and the memory array region; and
depositing and oxide material on the plurality of nitride layers to form a plurality of oxide layers in both the word line contact region and the memory array region.

2. The method of claim 1, further comprising recessing the plurality of nitride layers to form a plurality of second openings in both the word line contact region and the memory array region.

3. The method of claim 2, further comprising depositing a word line metal in the plurality of second openings simultaneously in both the word line contact region and the memory array region.

4. The method of claim 1, further comprising, prior to depositing the nitride material, trimming the plurality of silicon (Si) layers to form a plurality of trimmed silicon (Si) layers.

5. The method of claim 1, wherein the nitride material comprises silicon nitride (SiN) and wherein the oxide material comprises silicon oxide (SiOx).

6. The method of claim 1, wherein trimming the plurality of silicon (Si) layers comprises decreasing a thickness of each of the plurality of silicon (Si) layers from a first thickness to a second thickness.

7. The method of claim 6, wherein the first thickness is in a range of from 40 nm to 100 nm.

8. The method of claim 6, wherein the second thickness is in a range of from 10 nm to 40 nm.

9. The method of claim 3, wherein the word line metal comprises one or more of a metal, a metal nitride, a conductive metal compound, and a semiconductor material.

10. The method of claim 9, wherein the metal is selected from one or more of tungsten (W), molybdenum (Mo), tantalum (Ta), niobium (Nb), osmium (Os), zirconium (Zr), iridium (Ir), rhenium (Re), or titanium (Ti).

11. The method of claim 9, wherein the metal nitride is selected from one or more of titanium nitride (TiN), tantalum nitride (TaN), tungsten nitride (WN), molybdenum nitride (MoN), and zirconium nitride (ZrN).

12. The method of claim 9, wherein the conductive metal compound is selected from one or more of tungsten oxide (WOx), ruthenium oxide (RuOx), and iridium oxide (IrOx).

13. The method of claim 9, wherein the semiconductor material is selected from one or more of silicon (Si), silicon germanium (SiGe), and germanium (Ge).

14. A method of manufacturing a semiconductor device, the method comprising:
selectively etching a plurality of silicon germanium (SiGe) layers in both a word line contact region and a memory array region of a memory stack on a substrate to form a plurality of first openings adjacent a plurality of silicon (Si) layers;
depositing a nitride material on the plurality of silicon (Si) layers to form a plurality of nitride layers in both the word line contact region and the memory array region; and
depositing an oxide material on the plurality of nitride layers to form a plurality of oxide layers in both the word line contact region and the memory array region.

15. The method of claim 14, wherein the memory stack comprises alternating layers of the plurality of silicon (Si) layers and the plurality of silicon germanium (SiGe) layers.

16. The method of claim 14, further comprising, prior to depositing the nitride material, trimming the plurality of silicon (Si) layers to form a plurality of trimmed silicon (Si) layers.

17. The method of claim 14, wherein trimming the plurality of silicon (Si) layers comprises decreasing a thickness of each of the plurality of silicon (Si) layers from a first thickness to a second thickness decreasing a thickness of each of the plurality of silicon (Si) layers from a first thickness to a second thickness, the first thickness is in a range of from 40 nm to 100 nm and the second thickness is in a range of from 10 nm to 40 nm.

18. The method of claim 14, further comprising recessing the plurality of nitride layers to form a plurality of second openings in both the word line contact region and the memory array region.

19. The method of claim 18, further comprising depositing a word line metal in the plurality of second openings simultaneously in both the word line contact region and the memory array region.

20. The method of claim 19, wherein the word line metal comprises one or more of a metal, a metal nitride, a conductive metal compound, and a semiconductor material.
